(19) United States
(12) Patent Application Publication
(10) Pub. No.: US 2014/0217459 A1
(43) Pub. Date: Aug. 7, 2014

(54) SUBSTRATE FOR LIGHT EMITTING ELEMENT AND LIGHT EMITTING DEVICE

(71) Applicant: ASAHI GLASS COMPANY, LIMITED, Chiyoda-ku (JP)

(72) Inventor: Katsuyoshi NAKAYAMA, Chiyoda-ku (JP)

(73) Assignee: ASAHI GLASS COMPANY, LIMITED, Chiyoda-ku (JP)

(21) Appl. No.: 14/172,203

(22) Filed: Feb. 4, 2014

(30) Foreign Application Priority Data
Feb. 5, 2013 (JP) 2013-020402

(51) Int. Cl. H01L 25/16

(52) U.S. Cl. CPC H01L 25/167; H01L 25/165
USPC 257/99; 428/156

(57) ABSTRACT

A substrate for light emitting element has a substrate main body, a first recessed part, and a second recessed part. The substrate main body is made of a glass ceramic having a reflectance of 90% or more at a wavelength of 460 nm. The first recessed part is arranged on one main surface of the substrate main body, and has a first area on which a light emitting element is mounted. The second recessed part is arranged in the first recessed part except the first area, and has a second area on which a protection device is mounted.

### CROSS REFERENCE TO RELATED APPLICATION

This application is based upon and claims the benefit of priority from Japanese Patent Application No. 2013-020402 filed on Feb. 5, 2013; the entire contents of which are incorporated herein by reference.

### FIELD

The present invention relates to a substrate for light emitting element and a light emitting device using the same.

### BACKGROUND

In recent years, a light emitting device having a light emitting element such as a light-emitting diode (LED) element has been in practical use. Normally, in such a light emitting device, in order to protect a light emitting element and a wiring conductor mounted on a substrate for light emitting element, a sealing layer made of a silicone resin, an epoxy resin or the like is provided to cover these light emitting element and wiring conductor. Hereinafter, the substrate for light emitting element is simply referred to as a substrate. Further, a light emitting device in which a fluorescent material is dispersed in a sealing layer and white light is obtained through a combination of the fluorescent material and light emission of a light emitting element, has been in practical use.

In such a light emitting device, it has been known that the sealing layer is formed to have a hemispherical lens shape to improve color tone unevenness, light-collecting rate and the like. By forming the sealing layer to have the hemispherical lens shape, lengths of optical paths through which lights emitted from the light emitting element transmit through the sealing layer can be made to be equal in all directions. As a method of forming the sealing layer in the hemispherical lens shape, a method of molding a resin material using a mold having a shape opposite to that of the sealing layer in the hemispherical lens shape, and a method of supplying a resin material, through potting, onto a light emitting element mounted on a substrate have been known.

In the method of using the mold, a large number of sealing layers in the hemispherical lens shape can be molded at the same time, but, since the large number of sealing layers in the hemispherical lens shape are molded in a state of being mutually coupled, there is a need to divide the large number of sealing layers in the hemispherical lens shape into individual sealing layers in the hemispherical lens shape after the molding. On the other hand, in the method through the potting, since the resin material is independently supplied to each substrate, it is not necessary to perform the above-described division, which leads to better productivity.

Incidentally, to a light emitting device, a protection device for protection circuit for protection from overheat, overvoltage, overcurrent and the like is provided according to need. As the protection device, an electrostatic protection device such as a Zener diode and a transistor diode is provided. The protection device is provided to a lower part, a peripheral part or the like of a light emitting element, for example. Further, when the protection device is provided to the peripheral part of the light emitting element, and a substrate has a recessed part on which the light emitting element is mounted, there are a light emitting device in which the protection device is mounted on an inside of the recessed part, and a light emitting device in which the protection device is mounted on an outside of the recessed part.

When the sealing layer is formed on the recessed part of the substrate by a method using potting, generally, a resin material is supplied to a center portion of the recessed part, and the resin material flows to spread toward a peripheral portion of the recessed part, resulting in that the sealing layer in the hemispherical lens shape is formed. However, when the protection device is mounted on the inside of the recessed part, the protection device hinders the flow of the resin material, and there is a case that the sealing layer in the hemispherical lens shape is not formed in a predetermined shape.

Specifically, when the protection device is mounted on the inside of the recessed part, the protection device hinders the flow of the resin material, resulting in that the resin material easily flows in a direction of a side opposite to a side of the protection device with respect to the center portion of the recessed part. By the flow as described above, a position of a top portion being a highest portion of the sealing layer in the hemispherical lens shape is displaced in a direction of the side opposite to the side of the protection device with respect to the position of the center portion of the recessed part being the original position, and a light-extraction efficiency is lowered. Further, the light-extraction efficiency is lowered also when the resin material is overflowed from the recessed part due to the above-described flow. Furthermore, when the protection device and an adhesive such as a conductive paste with which the protection device is adhered have a black color or the like, the light-extraction efficiency is lowered due to light absorption of these protection device and adhesive.

As a method of suppressing the displacement of the position of the top portion, a method of mounting the protection device on the outside of the recessed part can be considered. However, when a size of the light emitting device is fixed, there is a need to reduce a size of the recessed part to mount the protection device on the outside of the recessed part, which lowers the light-extraction efficiency.

### SUMMARY

A substrate of an embodiment has a substrate main body, a first recessed part, and a second recessed part. The substrate main body is made of a glass ceramic having a reflectance of 90% or more at a wavelength of 460 nm. The first recessed part is arranged on one main surface of the substrate main body, and has a first area on which a light emitting element is mounted. The second recessed part is arranged in the first recessed part except the first area, and has a second area on which a protection device is mounted.

A light emitting device of an embodiment has a substrate main body, a first recessed part, a light emitting element, a second recessed part, a protection device, and a sealing layer. The substrate main body is made of a glass ceramic having a reflectance of 90% or more at a wavelength of 460 nm. The first recessed part is arranged on one main surface of the substrate main body, and has a first area on which the light emitting element is mounted. The light emitting element is arranged on the first area. The second recessed part is arranged in the first recessed part except the first area, and has a second area on which the protection device is mounted. The protection device is arranged on the second area. The sealing layer is arranged on the first recessed part, and seals the light emitting element and the protection device.

### BRIEF DESCRIPTION OF THE DRAWINGS

FIG. 1 is a plan view illustrating one embodiment of a substrate.

FIG. 2 is a sectional view taken along line A-A of the substrate illustrated in FIG. 1.

FIG. 3 is a top view of a first layer of the substrate illustrated in FIG. 1.

FIG. 4 is a top view of a second layer of the substrate illustrated in FIG. 1.

FIG. 5 is a top view of a third layer of the substrate illustrated in FIG. 1.

FIG. 6 is a bottom view of a fourth layer of the substrate illustrated in FIG. 1.

FIG. 7 is an explanatory diagram for explaining a size of each part when a light emitting element and a protection device are mounted on the substrate illustrated in FIG. 1.

FIG. 8 is a plan view illustrating a substrate having a third recessed part.

FIG. 9 is a sectional view taken along line B-B of the substrate illustrated in FIG. 8.

FIG. 10 is an explanatory diagram for explaining a size of each part when a light emitting element and a protection device are mounted on the substrate illustrated in FIG. 8.

FIG. 11 is a plan view illustrating one embodiment of a light emitting device.

FIG. 12 is a sectional view taken along line C-C of the light emitting device illustrated in FIG. 11.

### DETAILED DESCRIPTION

Hereinafter, embodiments of the present invention will be described, but, the present invention is not limited to these. A substrate of an embodiment is one for mounting a light emitting element thereon, and to the substrate, a sealing layer made of a resin material is provided, through potting, to cover the light emitting element.

The substrate of the embodiment has a substrate main body, a first recessed part, and a second recessed part. The substrate main body is made of a glass ceramic having a reflectance of 90% or more at a wavelength of 460 nm. The first recessed part is arranged on one main surface of the substrate main body, and has, in an inside thereof, a first area on which a light emitting element is mounted (area for light emitting element). The second recessed part is arranged in an inside of the first recessed part except the first area, and has, in an inside thereof, a second area on which a protection device is mounted (area for protection device).

Regarding the substrate with such a configuration, when the protection device is mounted and then a sealing layer in a hemispherical lens shape made of a resin material is formed through potting, the sealing layer in the hemispherical lens shape is favorably formed. Concretely, the sealing layer in the hemispherical lens shape in which a position of its top portion is close to that of a center portion of the first recessed part being the original position, is formed. Accordingly, a light-extraction efficiency is increased. Further, when the light emitting element is mounted on the center portion of the first recessed part, a misregistration between a center of the hemispherical lens and a center of the light emitting element is reduced, resulting in that the light-extraction efficiency is improved. Further, since the substrate main body made of the glass ceramic having the reflectance of 90% or more is provided, the light-extraction efficiency is further increased. Further, when the substrate main body is the glass ceramic, the substrate main body can be manufactured by stacking a plurality of green sheets, so that each of the first recessed part and the second recessed part can be easily formed by providing a through hole on a part of the green sheets.

### <Substrate for Light Emitting Element>

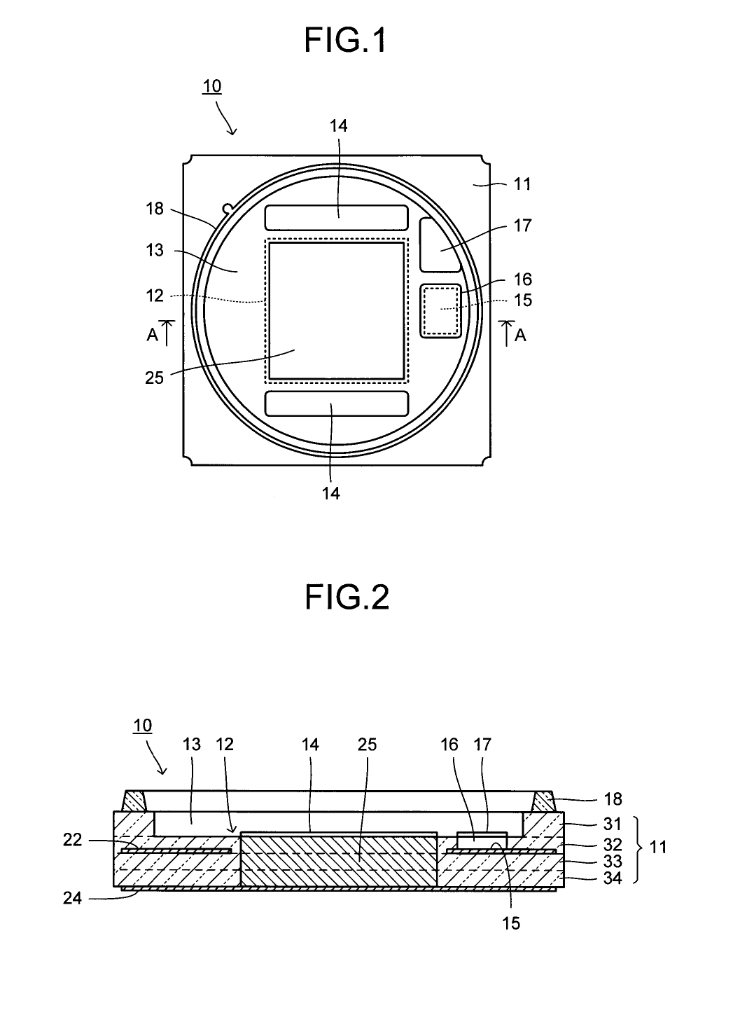

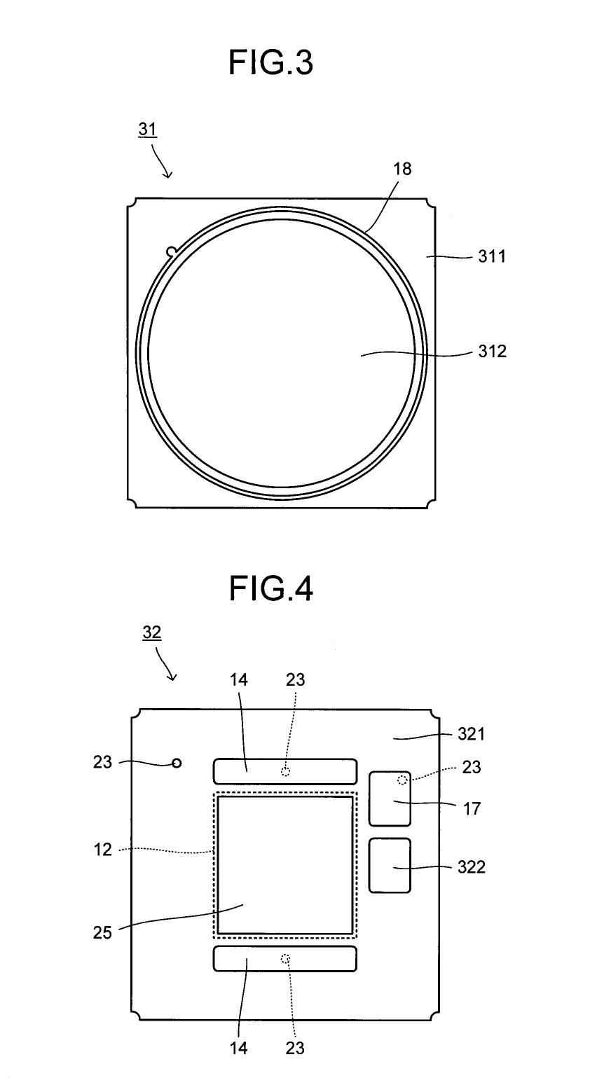

FIG. 1 is a plan view illustrating one embodiment of a substrate for light emitting element, FIG. 2 is a sectional view taken along line A-A of the substrate for light emitting element illustrated in FIG. 1, and FIG. 3 to FIG. 6 are views illustrating first to fourth layers of the substrate for light emitting element illustrated in FIG. 1, respectively. Note that FIG. 3 to FIG. 5 are top views of the first to third layers, respectively, and FIG. 6 is a bottom view of the fourth layer.

A substrate 10 has a substrate main body 11 made of a glass ceramic having a reflectance of 90% or more at a wavelength of 460 nm. The substrate main body 11 is not particularly limited as long as it is made of a glass ceramic having a predetermined reflectance. From a point of view of suppressing damage and the like when mounting a light emitting element and a protection device and during use after the mounting, the substrate main body 11 preferably has a deflective strength of 250 MPa or more, for example.

On one main surface of the substrate main body 11, there is provided a first recessed part 13 having, in an inside thereof, a first area 12 on which the light emitting element is mounted. A shape and the like of the first recessed part 13 are appropriately selected in accordance with shapes and the like of the light emitting element and the protection device. For example, the first recessed part 13 is set to have a size close to that of the substrate main body 11, and is set to have a circular shape. The first area 12 is set to have a shape similar to that of the light emitting element, and is arranged at a position on which the light emitting element is mounted. For example, the first area 12 is set to have a quadrangular shape, and is arranged at a center portion of the first recessed part 13. To the first area 12, a thermal via 25 is provided to penetrate through the substrate main body 11, for example. The thermal via 25 is set to have a quadrangular shape similar to the shape of the first area 12, for example. Note that the thermal via 25 has not only a function of heat radiation and the like, but also a function as a terminal for light emitting element which is electrically connected to the light emitting element, according to need.

To the first recessed part 13, a pair of terminals 14 for light emitting element to which the light emitting element is electrically connected are provided to sandwich the first area 12, for example. Each of the pair of terminals 14 for light emitting element has a rectangular shape whose length is close to that of the first area 12, and is arranged to extend along the first area 12, for example. Note that the pair of terminals 14 for light emitting element are electrically connected to the light emitting element, and in addition to that, they have a function of reflection, heat radiation and the like according to need.

Further, to an area of the first recessed part 13 except the area to which the first area 12 and the pair of terminals 14 for light emitting element are provided, there is provided a second recessed part 16 having, in an inside thereof, a second area 15 on which the protection device is mounted. The second area 15 is set to have a shape similar to that of the protection device, and is arranged at a position on which the protection device is mounted. For example, the second area 15 is set to have a quadrangular shape. The second recessed part 16 is provided to be adjacent to a side other than two sides to which the pair of terminals 14 for light emitting element for light emitting element are adjacently provided, out of four sides of the first area 12, for example. A shape of the second recessed part 16 is not particularly limited as long as the protection device can be mounted on the second recessed part 16. For example, the shape of the second recessed part 16 is preferably a quadrangular shape having a size similar to that of the second area 15, or a quadrangular shape larger than the above-described quadrangular shape.

Further, to an area of the first recessed part 13 except the area to which the first area 12, the pair of terminals 14 for light emitting element, and the second recessed part 16 are provided, there is provided a terminal 17 for protection device to which the protection device is electrically connected. A position and a shape of the terminal 17 for protection device are not particularly limited as long as the terminal 17 for protection device can be electrically connected to the protection device. For example, the terminal 17 for protection device is set to have a quadrangular shape having a size similar to that of the second recessed part 16, and is arranged adjacent to the second recessed part 16. Note that the terminal 17 for protection device is electrically connected to the protection device, and in addition to that, it has a function of reflection, heat radiation and the like according to need.

In the substrate main body 11, a convex guide part 18 that dams the resin material overflowed from the first recessed part 13 when performing potting, is provided around the first recessed part 13 according to need. The guide part 18 is set to have a ring shape which is slightly larger than the shape of the first recessed part 13, for example.

To the other main surface of the substrate main body 11, there are provided a pair of external terminals 21 (FIG. 6) electrically connected to an external circuit. Further, at a position between the pair of external terminals 21, an external conductor layer 24 as an external conductor layer used for the purpose of heat radiation and the like is provided. The external terminals 21 are electrically connected to the terminals 14 for light emitting element and the terminal 17 for protection device via internal conductor layers 22 as internal conductor layers provided to horizontally extend inside the substrate main body 11, and connection vias 23 provided to extend in a thickness direction inside the substrate main body 11 (FIG. 4 to FIG. 6). Note that the internal conductor layers 22 have not only a function as wiring but also a function of reflection, heat radiation and the like according to need. The external conductor layer 24 is connected to the light emitting element via the thermal via 25 provided to extend in the thickness direction inside the substrate main body 11.

The substrate main body 11 is formed of, for example, a first layer 31 to a fourth layer 34.

As illustrated in FIG. 3, the first layer 31 has a plate-shaped main body part 311, and a through hole 312 penetrating through the main body part 311 in the thickness direction. The through hole 312 forms the first recessed part 13 in the substrate main body 11. Further, on a surface of the main body part 311, the guide part 18 is provided to surround the first recessed part 13 according to need.

As illustrated in FIG. 4, the second layer 32 has a plate-shaped main body part 321. To a surface of the main body part 321, the first area 12, the pair of terminals 14 for light emitting element, and the terminal 17 for protection device are provided. Further, to the main body part 321, there are provided the thermal via 25 and a through hole 322 penetrating through the main body part 321 in the thickness direction. The through hole 322 forms the second recessed part 16 in the substrate main body 11. Further, there are provided, on the pair of terminals 14 for light emitting element and a lower part of the terminal 17 for protection device, the connection vias 23 penetrating through the main body part 321 in the thickness direction.

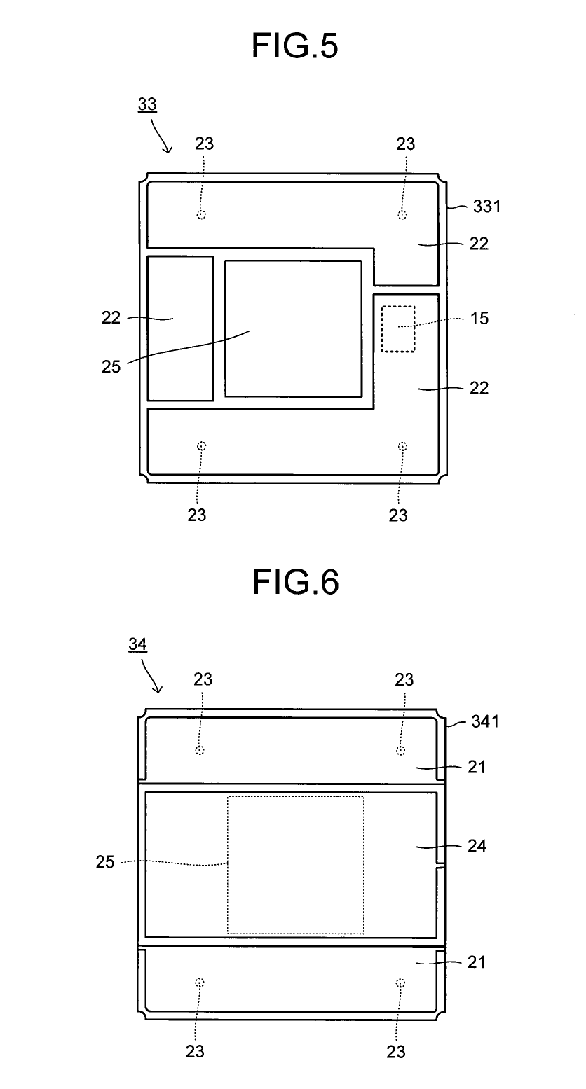

As illustrated in FIG. 5, the third layer 33 has a plate-shaped main body part 331. To a surface of the main body part 331, there are provided the internal conductor layers 22, which are divided into three parts, around an area to be a lower side of the first area 12 and corresponding to the first area 12, for example. Regarding the three internal conductor layers 22, for example, one of the internal conductor layers 22 (lower side in the drawing) is provided to overlap with one of the terminals 14 for light emitting element and the second area 15, and one of the other internal conductor layers 22 (upper side in the drawing) is provided to overlap with the other terminal 14 for light emitting element and the terminal 17 for protection device. Note that in the former internal conductor layer 22 (lower side in the drawing), a portion that overlaps with the second area 15 practically is the other terminal for protection device with respect to the above-described terminal 17. Specifically, the protection device is mounted on the above-described portion, and to the portion, one electrode (lower electrode) of the protection device is electrically connected. To lower parts of each of the above-described two internal conductor layers 22, for example, two connection vias 23 are respectively provided to penetrate through the main body part 331 in the thickness direction. Further, at a center portion of the main body part 331, the thermal via 25 is provided to penetrate through the main body part 331 in the thickness direction.

As illustrated in FIG. 6, the fourth layer 34 has a plate-shaped main body part 341. To a lower surface of the main body part 341, for example, the pair of external terminals 21 are provided, and the external conductor layer 24 used for heat radiation and the like is provided between the pair of external terminals 21. Further, to portions to which the pair of external terminals 21 are provided, the connection vias 23 are provided to penetrate through the main body part 341 in the thickness direction. The connection vias 23 of the fourth layer 34 are provided at positions which overlap with those of the connection vias 23 of the third layer 33 when the third layer 33 and the fourth layer 34 are overlapped. Further, at a portion to which the external conductor layer 24 is provided, the thermal via 25 is provided to penetrate through the main body part 341 in the thickness direction.

Composing materials of the terminals 14 for light emitting element, the terminal 17 for protection device, the external terminals 21, the internal conductor layers 22, the connection vias 23, the external conductor layer 24, and the thermal via 25 are not necessarily limited as long as they are conductive metal materials. As the conductive metal materials, it is preferable to employ conductive metal materials whose main component is copper, silver, gold or the like. Among these metal materials, it is more preferable to employ silver, or a silver alloy such as a silver-palladium alloy and a silver-platinum alloy.

From a point of view of reflectance, the silver alloy is preferably an alloy mainly made of silver, and it is more preferable that the silver alloy contains silver of 90 mass % or more. For example, when the silver-palladium alloy is employed, it is preferable that the alloy contains palladium of 10 mass % or less. Further, when the silver-platinum alloy is employed, it is preferable that the alloy contains platinum of 3 mass % or less. Particularly, the composing materials of the terminals 14 for light emitting element and the terminal 17 for protection device are preferably made of a simple substance of silver having a high reflectance.

The terminals 14 for light emitting element, the terminal 17 for protection device and the like are formed by printing a silver paste through a method of screen printing or the like, and performing firing, for example. The silver paste is made in a manner that, for example, a vehicle such as ethyl cellulose, and a solvent and the like according to need, are added to a silver powder or a silver alloy powder, to make the powder to be a paste form. A thickness of each of the terminals 14 for light emitting element, the terminal 17 for protection device and the like is preferably 5 to 20 μm.

It is preferable that each of the terminals 14 for light emitting element, the terminal 17 for protection device, the external terminals 21, and the external conductor layer 24 has a metal layer made of the above-described conductive metal material, and a protective layer provided on the metal layer and protecting the metal layer from oxidation and sulfuration. The protective layer is not necessarily limited as long as it is made of a conductive material having a function of protecting the metal layer. For example, as the protective layer, a plated layer such as a nickel-plated layer, a chrome-plated layer, a silver-plated layer, a nickel/silver-plated layer, a gold-plated layer, and a nickel/gold-plated layer, is preferable.

As the protective layer, it is preferable that a top layer of the protective layer is a gold-plated layer, from a point of view of favorable metal-to-metal connection, for example. Although the protective layer may be formed only of the gold-plated layer, it is more preferably formed of a nickel/gold-plated layer in which a gold-plated layer is provided on a nickel-plated layer. In this case, regarding a film thickness of the protective layer, it is preferable that the nickel-plated layer has a thickness of 2 to 20 μm, and the gold-plated layer has a thickness of 0.1 to 1 μm.

A composing material of the guide part 18 is not necessarily limited, and it may be a material similar to that of the substrate main body 11, a ceramic material or a resin material. The composing material of the guide part 18 is preferably a conductive metal material similar to the composing material of the terminals 14 for light emitting element, the terminal 17 for protection device and the like descried above, more preferably a conductive metal material whose main component is copper, silver, gold or the like, and is still more preferably silver, or a silver alloy such as a silver-palladium alloy and a silver-platinum alloy. It is preferable to use the composing material as described above, since it is possible to adopt a formation method similar to the formation method of the terminals 14 for light emitting element, the terminal 17 for protection device and the like.

The guide part 18 preferably has a metal layer made of the above-described conductive metal material, and a protective layer provided on the metal layer and protecting the metal layer from oxidation and sulfuration. The protective layer is not necessarily limited as long as it is made of a conductive material having a function of protecting the metal layer. For example, as the protective layer, a plated layer such as a nickel-plated layer, a chrome-plated layer, a silver-plated layer, a nickel/silver-plated layer, a gold-plated layer, and a nickel/gold-plated layer, is preferable.

It is preferable that a top layer of the protective layer of the guide part 18 is a gold-plated layer. Although the protective layer may be formed only of the gold-plated layer, it is more preferably formed of a nickel/gold-plated layer in which a gold-plated layer is provided on a nickel-plated layer. In this case, regarding a film thickness of the protective layer, it is preferable that the nickel-plated layer has a thickness of 2 to 20 μm, and the gold-plated layer has a thickness of 0.1 to 1 μm.

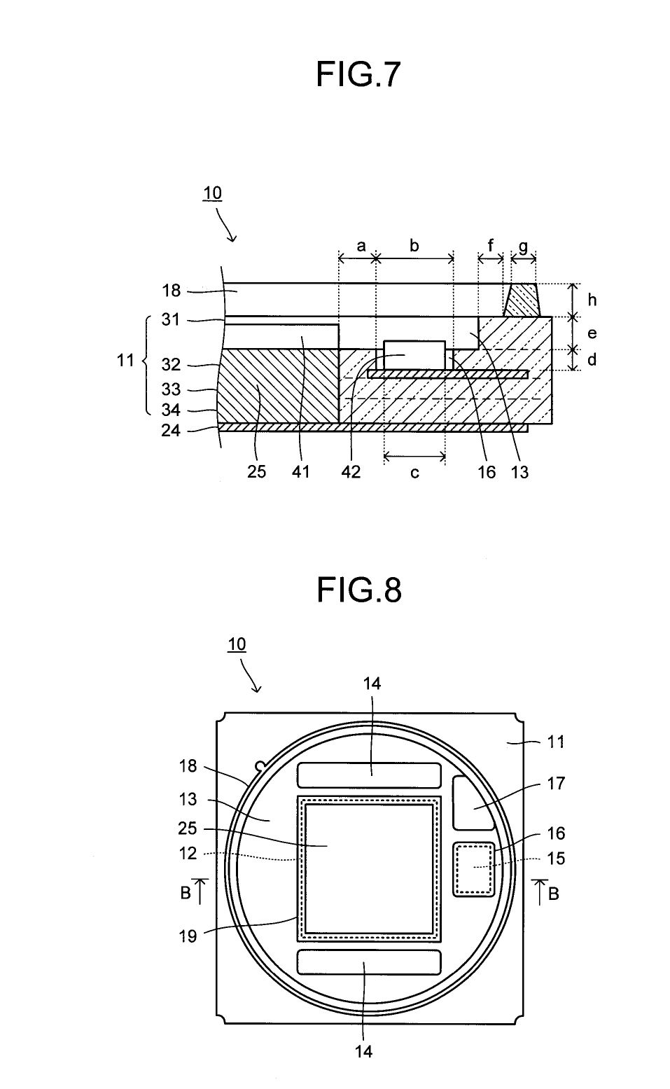

FIG. 7 is an explanatory diagram for explaining a size of each part of the substrate 10. Note that FIG. 7 illustrates a part of the sectional view illustrated in FIG. 2 in an enlarged manner, and illustrates a state where a light emitting element and a protection device are mounted. A size to be described hereinbelow is set to a size at a cross section passing through a center portion of a light emitting element 41 (first area 12) and a center portion of a protection device 42 (second area 15).

A distance a between the light emitting element 41 and the second recessed part 16 is preferably 0.05 to 0.30 mm. When the distance a is 0.05 mm or more, light emitted from the light emitting element 41 is suppressed to be absorbed in the second recessed part 16 or the protection device 42. Further, when the distance a is 0.30 mm or less, an excessive increase in size of the sealing layer in the hemispherical lens shape is suppressed. The distance a is more preferably 0.10 to 0.25 mm, and is still more preferably 0.15 to 0.20 mm.

It is preferable that a difference (b−c) between a width b of the second recessed part 16 and a width c of the protection device 42 is 0.10 to 0.30 mm. The protection device 42 is manufactured in a manner that, for example, a large number of the protection devices 42 are manufactured in a coupled manner and then are individually divided, so that a dimensional difference is easily generated due to a generation of burr and the like in accordance with such a division. When the difference (b−c) is 0.10 mm or more, even if there is a dimensional difference in the protection devices 42, it is possible to stably mount the protection device 42 on the second recessed part 16. Further, when the difference (b−c) is 0.30 mm or less, an excessive increase in size of the sealing layer in the hemispherical lens shape is suppressed. The width b of the second recessed part 16 is more preferably set in a manner that the difference (b−c) is 0.15 to 0.25 mm.

It is preferable that a ratio d/D of a depth d of the second recessed part 16 to a thickness D (not illustrated) of the protection device 42 is 0.7 to 1.1. When the ratio d/D is 0.7 or more, an excessive projection of a head portion of the protection device 42 from the second recessed part 16 is suppressed. Accordingly, it is possible to suppress a flow variation of the resin material caused by the protection device 42, after the potting of the resin material. Further, when the ratio d/D is 1.1 or less, the head portion of the protection device 42 is suppressed to be excessively low, and it is easy to perform wire bonding on the protection device 42. Further, a position of a top portion of the sealing layer in the hemispherical lens shape can be suppressed to be displaced toward the second recessed part 16 side due to the flow of the resin material into the second recessed part 16. The ratio d/D is more preferably 0.8 to 1.0.

A depth e of the first recessed part 13 is preferably 0.05 to 0.30 mm. When the depth e is 0.05 mm or more, it is easy to hold the resin material during the potting. Meanwhile, when the depth e is 0.30 mm or less, a thickness of the entire substrate 10 is reduced, and a reduction in the light-extraction efficiency caused when the light emitting element 41 is arranged at an excessively low position, is suppressed. The depth e is more preferably 0.10 to 0.15 mm.

A distance f between the first recessed part 13 and the guide part 18 is preferably 0.05 to 0.30 mm. When the distance f is 0.05 mm or more, a period of time up to when the resin material overflowed from the first recessed part 13 reaches the guide part 18 is long to some degree, so that the sealing layer in the hemispherical lens shape is formed in a stable manner. Meanwhile, when the distance f is 0.30 mm or less, an excessive increase in size of the sealing layer in the hemispherical lens shape is suppressed. The distance f is more preferably 0.10 to 0.20 mm.

A width g of the guide part 18 is preferably 0.10 to 0.30 mm. When the width g is 0.10 mm or more, the guide part 18 can be formed in a stable manner through the screen printing, and the shape of the sealing layer in the hemispherical lens shape easily becomes stable. When the width g is 0.30 mm or less, an increase in size of the substrate 10 is suppressed, and absorption of light by the guide part 18 is suppressed, resulting in that the reduction in the light-extraction efficiency is suppressed. The width g is more preferably 0.15 to 0.20 mm.

A height h of the guide part 18 is preferably 0.02 to 0.10 mm. When the height h is 0.02 mm or more, it is possible to effectively dam the resin material overflowed from the first recessed part 13. Meanwhile, when the height h is 0.10 mm or less, the absorption of light by the guide part 18 is suppressed, and the reduction in the light-extraction efficiency is suppressed. The height h is preferably 0.03 to 0.06 mm.

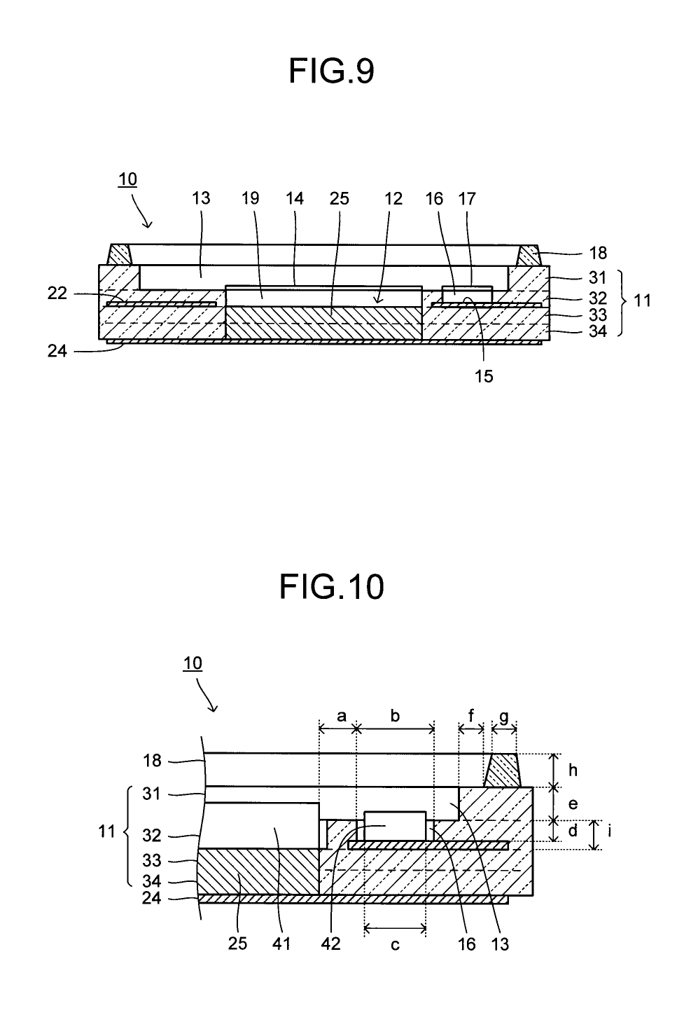

Although the substrate 10 of the present invention is described as above, the configuration thereof can be appropriately changed according to need without departing from the scope of the present invention. For example, as illustrated in FIG. 8 and FIG. 9, it is also possible that a third recessed part 19 having the first area 12 on which the light emitting element is mounted, is further provided to the inside of the first recessed part 13. Also in a case where the third recessed part 19 is provided, a dimension of each part can be set in a manner similar to the case where the third recessed part 19 is not provided, as illustrated in FIG. 10, for example.

### <Light Emitting Device>

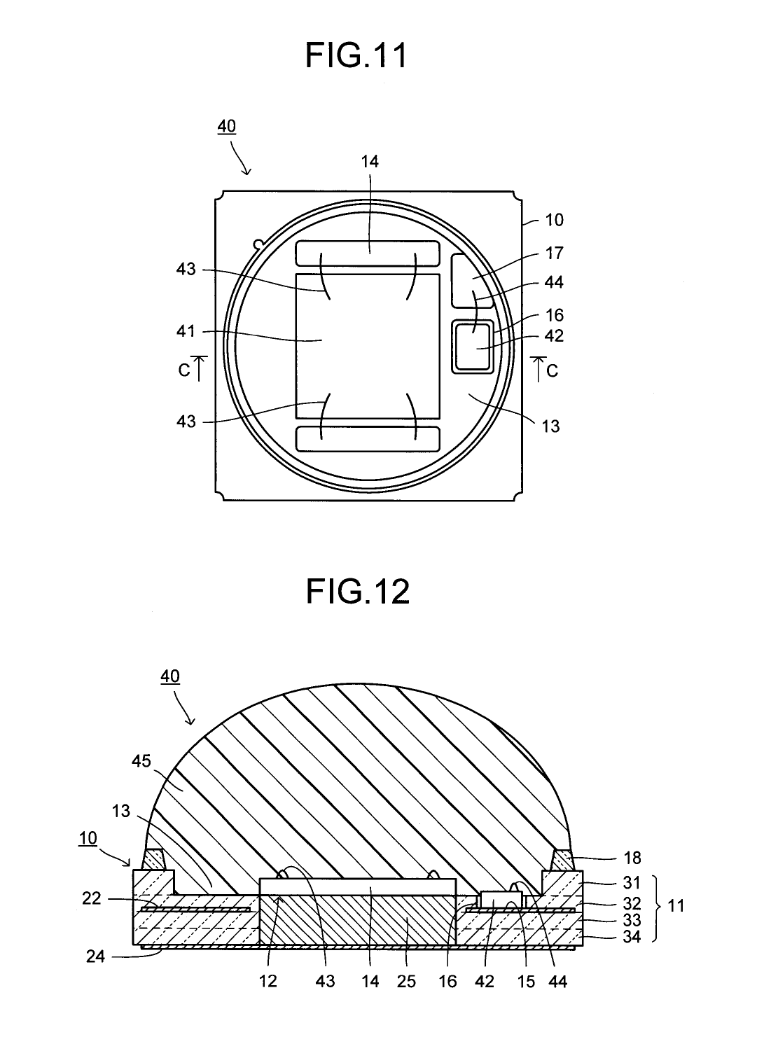

FIG. 11 is a plan view illustrating one embodiment of a light emitting device, and FIG. 12 is a sectional view taken along line C-C of the light emitting device illustrated in FIG. 11. Note that FIG. 11 illustrates a state where the sealing layer is removed.

A light emitting device 40 has the above-described substrate 10. On the first area 12 of the substrate 10, the light emitting element 41 such as an LED element is mounted. Although not illustrated, the light emitting element 41 has a pair of electrodes on its upper surface, and the pair of electrodes are electrically connected to the pair of terminals 14 for light emitting element, respectively, by bonding wires 43. Further, the light emitting device 40 has a heat radiating part on its lower surface, for example, and the heat radiating part is connected to the thermal via 25.

Further, on the second area 15 provided to the inside of the second recessed part 16, the protection device 42 such as a Zener diode is mounted. A lower surface of the protection device 42 is electrically connected to the internal conductor layer 22, and an upper surface of the protection device 42 is electrically connected to the terminal 17 for protection device by a bonding wire 44. For example, when the Zener diode is mounted as the protection device 42, the Zener diode is electrically connected in parallel with the light emitting element 41 and in a direction opposite to that of the light emitting element 41. Accordingly, the light emitting element 41 is protected from reverse voltage and overvoltage.

To the inside of the first recessed part 13, a sealing layer 45 in a hemispherical lens shape made of a translucent resin material is provided to cover the light emitting element 41, the protection device 42 and the like, through potting. The sealing layer 45 in the hemispherical lens shape preferably covers up to an outer end portion of an upper surface of the guide part 18. When the sealing layer 45 in the hemispherical lens shape is set to have the shape of covering up to the outer end portion of the upper surface of the guide part 18 as described above, a position of a top portion of the sealing layer 45 in the hemispherical lens shape particularly is close to that of a center of the first recessed part 13 being the original position, which is preferable.

As the resin material, it is preferable to employ a silicone resin having good light resistance and heat resistance. Note that as the resin material, it is also possible to employ an epoxy resin, a fluorocarbon resin or the like. As the silicone resin, a publicly-known silicone resin as a resin material for sealing in a light emitting device can be used without particular limitation.

Further, by mixing or dispersing a phosphor or the like in the resin material, it is possible to adjust light obtained as the light emitting device 40 to have a desired emission color. Specifically, the phosphor is mixed or dispersed in the translucent resin material such as the silicone resin that forms the sealing layer 45. As a result of this, the phosphor excited by light emitted from the light emitting element 41 emits visible light, and a color of the visible light and a color of the light emitted from the light emitting element 41 are mixed, which enables to obtain a desired emission color as the light emitting device 40. A type of the phosphor is not particularly limited, and is appropriately selected in accordance with a type of light emitted from the light emitting element 41 and an intended emission color.

As described above, in the light emitting device 40, the protection device 42 is mounted on the inside of the second recessed part 16. Accordingly, a flow of the resin material when forming the sealing layer 45 in the hemispherical lens shape through the potting is favorable, resulting in that the position of the top portion of the sealing layer 45 in the hemispherical lens shape is close to that of the center of the first recessed part 13 being the original position. It is preferable that the sealing layer 45 in the hemispherical lens shape is provided to cover up to the outer end portion of the upper surface of the guide part 18 so that the position of the top portion of the sealing layer 45 in the hemispherical lens shape is further close to that of the center of the first recessed part 13 being the original position. In combination with the above-described fact, since the substrate main body 11 is made of the glass ceramic having the reflectance of 90% or more, the light-extraction efficiency is particularly increased.

### <Manufacturing Method>

Next, a manufacturing method of the substrate 10 and the light emitting device 40 will be described. The substrate 10 is manufactured through, for example, (A) a green sheet producing process, (B) a conductor layer forming process, (C) a stacking process, and (D) a firing process. The light emitting device 40 is manufactured through, for example, the above-described processes, and thereafter, (E) an element mounting process, and (F) a sealing process.

### (A) Green Sheet Producing Process

By using a glass ceramic composition containing a glass powder and a ceramic powder, a green sheet for manufacturing the substrate main body 11 is produced. Note that regarding the green sheet, each of green sheets to be the main body part 311 of the first layer 31 to the main body part 341 of the fourth layer 34 is produced.

The green sheet is produced in the following manner. At first, to the glass ceramic composition containing the glass powder and the ceramic powder, a binder, and according to need, a plasticizer, a dispersing agent, a solvent and the like are added, thereby preparing a slurry. The slurry is molded in a sheet shape through a doctor blade method or the like, and dried to produce the green sheet.

As the glass powder for producing the green sheet, one having glass transition temperature (Tg) of 550 to 700° C. is preferable. When Tg is 550° C. or more, it is easy to perform degreasing. Meanwhile, when Tg is 700° C. or less, a shrinkage start temperature is low, resulting in that a good dimensional accuracy is provided. Further, it is preferable that in the glass powder, a crystal is precipitated when firing is performed at 800 to 930° C. The precipitation of crystal enables to obtain a sufficient mechanical strength.

Such a glass powder preferably contains, in mol % on an oxide basis, SiO₂ of 57 to 65%, B₂O₃ of 13 to 18%, Al₂O₃ of 3 to 8%, at least either of Na₂O and K₂O of 0.5 to 6%, and CaO of 9 to 23%. When the glass powder with such a composition is used, a surface flatness of the substrate 10 is improved.

The glass powder is obtained in a manner that a glass having a predetermined composition is produced through a fusion method, and the glass is ground through a dry grinding method or a wet grinding method. When the wet grinding method is employed, water or ethyl alcohol is suitably used as a solvent. As a grinder, for example, a roll mill, a ball mill, a jet mill or the like can be cited.

D₅₀ of the glass powder is preferably 0.5 to 2 μm. When the D₅₀ of the glass powder is 0.5 μm or more, an agglomeration of glass powder is suppressed, so that handling is easy, and further, it is easy to uniformly disperse the glass powder. Meanwhile, when the D₅₀ of the glass powder for substrate is 2 μm or less, an increase in glass softening temperature and an occurrence of insufficient sintering are suppressed. A grain size is adjusted by performing classification or the like according to need after the grinding, for example. The D₅₀ (50% grain size) in the present specification indicates one measured by using a laser diffraction/scattering grain size distribution measuring apparatus.

As the ceramic powder, one which is conventionally used for producing a glass ceramic can be used, and, for example, an alumina powder, a zirconia powder, a mixture of the alumina powder and the zirconia powder, or the like can be suitably used. It is particularly preferable that the alumina powder and a ceramic powder having a refractive index higher than that of alumina (referred to as high refractive index ceramic powder) are used in a combined manner.

The high refractive index ceramic powder is a component for improving the reflectance of the substrate 10 being a sintered body, and as the powder, for example, a titania powder, a zirconia powder, a stabilized zirconia powder or the like can be cited. Although a refractive index of alumina is about 1.8, a refractive index of titania is about 2.7, a refractive index of zirconia is about 2.2, and thus each of titania and zirconia has the refractive index higher than that of alumina. D₅₀ of each of the ceramic powders is preferably 0.5 to 4 μM.

When the ceramic powder and the glass powder as described above are mixed by blending the glass powder of 30 to 50 mass %, and the ceramic powder of 50 to 70 mass %, for example, a glass ceramic composition is obtained. Further, when a binder, and according to need, a plasticizer, a dispersing agent, a solvent and the like are added to the glass ceramic composition, a slurry is obtained.

As the binder, for example, polyvinyl butyral, an acrylic resin or the like is suitably used. As the plasticizer, for example, dibutyl phthalate, dioctyl phthalate, butyl benzyl phthalate or the like is suitably used. As the solvent, for example, an organic solvent such as toluene, xylene, 2-propanol, and 2-buthanol is suitably used.

The slurry obtained as above is molded in a sheet shape through the doctor blade method or the like, and dried to produce the green sheet. Regarding the green sheet, four types of the green sheets to be the main body part 311 of the first layer 31 to the main body part 341 of the fourth layer 34 are produced, for example. On the respective green sheets, through holes to be the first recessed part 13, the second recessed part 16, the connection vias 23, and the thermal via 25 are formed according to the types of the green sheets, by using a die or a punching machine.

### (B) Conductor Layer Forming Process

On the respective green sheets, conductive pastes are applied to or filled in predetermined positions, according to the types of the green sheets, thereby forming unfired conductor layers. As the unfired conductor layers, ones to be the terminals 14 for light emitting element, the terminal 17 for protection device, the external terminals 21, the internal conductor layers 22, the connection vias 23, the external conductor layer 24, and the thermal via 25 can be cited (FIG. 4 to FIG. 6). Further, when the guide part 18 is made of a conductive material, the conductive paste is applied to form an unfired conductor layer to be the guide part 18 (FIG. 3). The conductive paste is applied through, for example, a screen printing.

As the conductive paste, for example, one obtained by adding a vehicle such as ethyl cellulose, and a solvent and the like according to need, to a powder of conductive metal whose main component is copper, silver, gold or the like, to make the powder to be a paste form is used. Here, as the conductive metal powder, it is preferable to use a powder of silver or a silver alloy (an alloy of silver and platinum or an alloy of silver and palladium).

### (C) Stacking Process

The green sheets obtained through the (B) conductor layer forming process are stacked in a predetermined order, and then integrated through a thermocompression bonding. Accordingly, an unfired substrate 10 is obtained.

### (D) Firing Process

Degreasing of the binder and the like is performed, according to need, on the unfired substrate 10 obtained through the (C) stacking process, and then firing for sintering the glass ceramic composition and the like is performed, to thereby obtain the substrate 10.

A degreasing temperature is preferably 500 to 600° C. A degreasing time is preferably 1 to 10 hours. When the degreasing temperature is 500° C. or more and the degreasing time is 1 hour or more, the binder and the like are effectively removed. Meanwhile, when the degreasing temperature is 600° C. or less and the degreasing time is 10 hours or less, a reduction in productivity and the like is suppressed.

Regarding a firing temperature, by taking an acquisition of fine structure of the substrate 10 and the productivity into consideration, the temperature can be appropriately adjusted within a temperature range of 800 to 930° C., in which the temperature is preferably 850 to 900° C., and is more preferably 860 to 880° C. Further, a firing time is preferably 20 to 60 minutes. When the temperature is 800° C. or more, the fine structure can be effectively obtained. Meanwhile, when the firing temperature is 930° C. or less, a deformation of the substrate 10 is suppressed, which improves the productivity and the like. Further, when the temperature is 880° C. or less, an excessive softening of silver paste layer is suppressed, resulting in that a predetermined shape is maintained.

After the firing, a protective layer which is generally used for conductor protection such as a nickel-plated layer, a chrome-plated layer, a silver-plated layer, a nickel/silver-plated layer, a gold-plated layer, and a nickel/gold-plated layer is formed, according to need, to cover the terminals 14 for light emitting element, the terminal 17 for protection device, the guide part 18, the external terminals 21, the external conductor layer 24, and the thermal via 25. Among these, the nickel/gold-plated layer is preferably used. Regarding the nickel/gold-plated layer, the nickel-plated layer is formed through electrolytic plating by using a nickel sulfamate bath or the like, and the gold-plated layer is formed through electrolytic plating by using a gold potassium cyanide bath or the like, for example.

### (E) Element Mounting Process

The light emitting element 41 such as an LED element and the protection device 42 such as a Zener diode are mounted on the first area 12 and the second area 15, respectively, of the substrate 10 obtained through the (D) firing process. Thereafter, the light emitting element 41 and the terminals 14 for light emitting element are electrically connected by using the bonding wires 43, and the protection device 42 and the terminal 17 for protection device are electrically connected by using the bonding wire 44. Note that the protection device 42 is electrically connected to the internal conductor layer 22 at a lower surface thereof.

### (F) Sealing Process

Potting of a thermosetting silicone resin material having a flowability is performed to cover the light emitting element 41 and the protection device 42 mounted on the substrate 10. Thereafter, the thermosetting silicone resin material is cured through heating or the like. Accordingly, the sealing layer 45 in the hemispherical lens shape is formed.

At this time, since the protection device 42 is mounted on the inside of the second recessed part 16, a flow of the resin material is favorable, and the position of the top portion of the sealing layer 45 in the hemispherical lens shape is close to that of the center of the first recessed part 13 being the original position. Further, when the guide part 18 is provided, the resin material overflowed from the first recessed part 13 is dammed by the guide part 18. In this case, when the sealing layer 45 in the hemispherical lens shape is provided to cover up to the outer end portion of the upper surface of the guide part 18, the position of the top portion of the sealing layer 45 in the hemispherical lens shape is further close to that of the center of the first recessed part 13 being the original position.

Although the manufacturing method of the substrate 10 and the light emitting device 40 is described above, the number of green sheets used for manufacturing the substrate 10 is not necessarily limited to four, and is appropriately selected according to the structure of the substrate 10 and the light emitting device 40. Further, it is also possible that a multi-cavity coupled substrate is produced, and the substrate is divided to produce the substrate 10. In this case, the division may be performed before or after the mounting of the light emitting element 41 and the like, as long as it is performed after the firing.

### WORKING EXAMPLES

Hereinafter, working examples of the present invention will be described. Note that the present invention is not limited to the following working examples.

### Examples 1 to 9

The substrate 10 having the third recessed part 19 as illustrated in FIG. 8 and FIG. 9 was manufactured through a method to be described below, and the light emitting device 40 was manufactured by using the substrate 10. Note that examples 1 to 9 are working examples of the present invention.

### (Manufacture of Substrate 10)

Materials were blended and mixed to achieve, in mol % on an oxide basis, SiO₂ of 60.4%, B₂O₃ of 15.6%, Al₂O₃ of 6%, CaO of 15%, K₂O of 1%, and Na₂O of 2%. This material mixture was put into a platinum crucible to be melted at 1600° C. for 60 minutes, and then a glass in a molten state was flowed out and cooled. This glass was ground for 40 hours by using a ball mill made of alumina to produce a glass powder. Note that as a solvent used for the grinding, ethyl alcohol was employed.

The glass powder of 35 mass %, an alumina powder (manufactured by Showa Denko K.K., trade name: AL-45H) of 40 mass %, and a zirconia powder (manufactured by DAIICHI KIGENSO KAGAKU KOGYO CO., LTD., trade name: HSY-3F-J) of 25 mass % were blended and mixed to produce a glass ceramic composition. An organic solvent (mixture of toluene, xylene, 2-propanol, and 2-butanol in a mass ratio of 4:2:2:1) of 15 g, a plasticizer (di-2-ethylhexyl phthalate) of 2.5 g, polyvinyl butyral (manufactured by Denki Kagaku Kogyo Kabushiki Kaisha, trade name: PVK#3000K) as a binder of 5 g, and a dispersing agent (manufactured by BYK Japan K.K., trade name: BYK180) of 0.5 g were blended and mixed in the glass ceramic composition of 50 g, to thereby prepare a slurry.

Onto PET films, the slurry was applied through a doctor blade method and dried, and the resultants were stacked according to need, thereby producing green sheets. Note that regarding the green sheets, four types of green sheets to be the main body part 311 of the first layer 31 to the main body part 341 of the fourth layer 34 were produced. On the green sheets, through holes to be the first recessed part 13, the second recessed part 16, the third recessed part 19, the connection vias 23, and the thermal via 25 were formed, according to the types of the green sheets, by using a punching machine (FIG. 3 to FIG. 6). Note that the substrate 10 was manufactured in a manner that a multi-cavity coupled substrate in which a large number of the substrates 10 as described above were coupled was fired, and divided after the firing. The description hereinbelow is an explanation regarding one section to be one substrate 10 in the coupled substrate.

A silver powder (manufactured by DAIKEN CHEMICAL CO., LTD., trade name: S400-2) and ethyl cellulose as a vehicle were blended in a mass ratio of 85:15. This was dispersed in α-terpineol as a solvent so that a solid content became 85 mass %. Thereafter, the resultant was kneaded in a porcelain mortar for 1 hour, and further dispersed three times by three rolls to produce a silver paste.

The silver paste was applied to or filled in each of the green sheets through a screen printing method to form unfired conductor layers. As the unfired conductor layers, ones to be the terminals 14 for light emitting element, the terminal 17 for protection device, the guide part 18, the external terminals 21, the internal conductor layers 22, the connection vias 23, the external conductor layer 24, and the thermal via 25 were formed (FIG. 3 to FIG. 6).

Next, the respective green sheets were overlapped, and then integrated through a thermocompression bonding to obtain an unfired coupled substrate. On the unfired coupled substrate, a division line (cut line) for performing division was formed. After that, there was performed degreasing in which the substrate was maintained at 550° C. for 5 hours, and there was further performed firing in which the substrate was maintained at 870° C. for 30 minutes, to thereby manufacture a coupled substrate. Thereafter, nickel and gold plating was performed on portions to be the terminals 14 for light emitting element, the terminal 17 for protection device, the guide part 18, the external terminals 21, the external conductor layer 24, the thermal via 25, and the second area 15 in the internal conductor layer 22. The coupled substrate after being subjected to the plating was divided along the division line, to thereby manufacture the substrate 10.

Here, as presented in Table 1, the substrates 10 of the examples 1 to 9 have a different ratio d/D of the depth d of the second recessed part 16 to the thickness D of the Zener diode, a different height h of the guide part 18, and a different depth i of the third recessed part 19. Here, as a value of the ratio d/D is larger, a proportion of the Zener diode housed in the second recessed part 16 is increased. On the contrary, as the value of the ratio d/D is smaller, it is easy for the Zener diode to be projected from the second recessed part 16.

The ratio d/D, particularly the depth d, was adjusted by changing a thickness of the green sheet to be the main body part 321 of the second layer 32. The distance f can be adjusted by changing a position of applying the silver paste. The height h was adjusted by changing a thickness of applied silver paste and a plating thickness. Here, when the height h is 35.0 μm, a thickness of silver conductor is 18 μm, a nickel plating thickness is 16.5 μm, and a gold plating thickness is 0.5 μm. When the height h is 10 μm, a thickness of silver conductor is 5 μm, a nickel plating thickness is 4.5 and a gold plating thickness is 0.5 μm. When the height h is 20 μM, a thickness of silver conductor is 12 μm, a nickel plating thickness is 7.5 μm, and a gold plating thickness is 0.5 μm.

Dimensions of main parts other than the parts described above are as follows.

Distance a between the light emitting element 41 and the second recessed part 16: 0.2 mm

Width b of the second recessed part 16: 0.50 mm

Width c of the protection device 42: 0.30 mm

Depth e of the first recessed part 13: 0.15 mm

Width g of the guide part 18: 0.15 mm

Substrate 10: outer size of 3.5 mm×3.5 mm, thickness of 0.5 mm

First recessed part 13: diameter of 2.7 mm

Second recessed part 16: outer size of 0.5 mm×0.5 mm

Third recessed part 19: outer size of 1.4 mm×1.4 mm

Further, a test piece for measuring reflectance (thickness of 500 μm) was separately produced by using similar green sheets and performing degreasing and firing similar to those in the manufacture of the substrate 10. When a reflectance of a surface of the test piece was measured at a wavelength of 460 nm, the reflectance was 90% or more. Here, for the measurement of the reflectance, a spectroscopy system (manufactured by Ocean Optics Inc., trade name: USB2000) using an integrating sphere with light source (manufactured by Ocean Optics Inc., trade name: ISP-REF) was employed. The light source is a tungsten-halogen light source whose color temperature is 3100 K.

### <Light Emitting Device>

Next, on the first area 12 in the inside of the first recessed part 13 of the substrate 10, an LED element having an outer size of 1.2 mm×1.2 mm and a thickness of 0.19 mm was mounted as the light emitting element 41. Further, on the second area 15 in the inside of the second recessed part 16, a Zener diode having an outer size of 0.3 mm×0.3 mm and a thickness of 0.12 mm (D) was mounted as the protection device 42. After that, a curable silicone resin material (manufactured by Shin-Etsu Chemical Co., Ltd., trade name: LPS-3421T) was injected into the inside of the first recessed part 13 by using a dispenser (manufactured by Musashi engineering Inc., trade name: ML-5000XII) to cover the LED element and the Zener diode. Note that the injection was performed so that the sealing layer 45 in the hemispherical lens shape covered up to the outer end portion of the upper surface of the guide part 18. Thereafter, heating was performed at 100° C. for 1 hour, and then heating was performed at 150° C. for 3 hours to cause curing, to thereby form the sealing layer 45 in the hemispherical lens shape.

### Example 10

A substrate was manufactured in a similar manner to the example 1 except that the through hole to be the second recessed part for mounting the light emitting element was not formed on the green sheet to be the main body part of the second layer. Thereafter, the LED element and the Zener diode were mounted in a similar manner to the above-described example 1, and then the sealing layer in the hemispherical lens shape was formed to manufacture a light emitting device. Note that the Zener diode was mounted at a position similar to that of the above-described example 1 except that the height thereof to be mounted was different. The example 10 corresponds to a comparative example of the present invention.

### <Evaluation>

Regarding each of the light emitting devices of the examples 1 to 10, a distance in a horizontal direction between a position of a center of the LED element and a position of a top portion of the sealing layer in the hemispherical lens shape was measured. The light emitting device was cut at a cross section passing through a center in plan view of each of the LED element and the Zener diode, and a distance in the horizontal direction between a position of the center of the LED element and a position of the top portion of the sealing layer in the hemispherical lens shape in the cross section was measured by using a measuring microscope. The above-described distance is presented as a distance L in Table 1.

TABLE 1

| | a | b-c | d/D | e | f | g | h | i | L |
|---|---|---|---|---|---|---|---|---|---|
| | [mm] | [mm] | [—] | [mm] | [mm] | [mm] | [μm] | [mm] | [mm] |
| Example 1 | 0.2 | 0.2 | 0.8 | 0.15 | 0.1 | 0.15 | 35 | 0.835 | 0.03 |
| Example 2 | 0.2 | 0.2 | 0.7 | 0.15 | 0.1 | 0.15 | 35 | 0.735 | 0.07 |
| Example 3 | 0.2 | 0.2 | 1 | 0.15 | 0.1 | 0.15 | 35 | 1.035 | 0.05 |
| Example 4 | 0.2 | 0.2 | 1.1 | 0.15 | 0.1 | 0.15 | 35 | 1.135 | 0.03 |
| Example 5 | 0.2 | 0.2 | 1.2 | 0.15 | 0.1 | 0.15 | 35 | 1.235 | 0.12 |
| Example 6 | 0.2 | 0.2 | 0.8 | 0.15 | 0.1 | 0.15 | 10 | 0.835 | 0.25 |
| Example 7 | 0.2 | 0.2 | 0.8 | 0.15 | 0.1 | 0.15 | 20 | 0.835 | 0.09 |
| Example 8 | 0.2 | 0.2 | 0.8 | 0.15 | 0.1 | 0.15 | 35 | 0.835 | 0.21 |
| Example 9 | 0.2 | 0.2 | 0.8 | 0.15 | 0.1 | 0.15 | 35 | 0.835 | 0.21 |
| Example 10 | 0.2 | 0.2 | — | 0.15 | 0.1 | 0.15 | 35 | 0.035 | 0.40 |

As is apparent from Table 1, in the substrate of the example 10 which does not have the second recessed part, the distance L indicating a displacement of the position of the top portion is large. On the other hand, in each of the substrates of the examples 1 to 9 having the second recessed part, the distance L is small. In particular, in each of the substrates of the examples 1 to 4 and 7 in which the depth d of the second recessed part is 0.7 to 1.1, the distance L is 0.1 mm or less, resulting in that the displacement of the position of the top portion is effectively suppressed.

What is claimed is:

1. A substrate for light emitting element, comprising:
a substrate main body made of a glass ceramic having a reflectance of 90% or more at a wavelength of 460 nm;
a first recessed part arranged on one main surface of the substrate main body, and having a first area on which a light emitting element is mounted; and
a second recessed part arranged in the first recessed part except the first area, and having a second area on which a protection device is mounted.

2. The substrate for light emitting element according to claim 1,
wherein a ratio of a depth of the second recessed part to a thickness of the protection device is 0.7 to 1.1.

3. The substrate for light emitting element according to claim 1,
wherein a distance between the first area and the second recessed part is 0.05 to 0.30 mm.

4. The substrate for light emitting element according to claim 1,
wherein a depth of the first recessed part is 0.05 to 0.30 mm.

5. The substrate for light emitting element according to claim 1,
wherein the glass ceramic is a sintered body of a glass ceramic composition containing a glass powder and a ceramic powder; and
wherein the glass powder contains, in mol % on an oxide basis, SiO₂ of 57 to 65%, B₂O₃ of 13 to 18%, Al₂O₃ of 3 to 8%, at least either of Na₂O and K₂O of 0.5 to 6%, and CaO of 9 to 23%.

6. The substrate for light emitting element according to claim 1, further comprising
a convex guide part arranged around the first recessed part, and damming a resin material at a time of performing potting.

7. The substrate for light emitting element according to claim 6,
wherein a height of the guide part is 0.02 to 0.10 mm.

8. The substrate for light emitting element according to claim 6,
wherein a width of the guide part is 0.10 to 0.30 mm.

9. The substrate for light emitting element according to claim 6,
wherein the guide part has a metal layer.

10. The substrate for light emitting element according to claim 6,
wherein the guide part further has a plated layer disposed on the metal layer.

11. A light emitting device, comprising:
a substrate main body made of a glass ceramic having a reflectance of 90% or more at a wavelength of 460 nm;
a first recessed part arranged on one main surface of the substrate main body, and having a first area on which a light emitting element is mounted;
the light emitting element arranged on the first area;
a second recessed part arranged in the first recessed part except the first area, and having a second area on which a protection device is mounted;
the protection device arranged on the second area; and
a sealing layer made of a resin material which is arranged on the first recessed part, and which seals the light emitting element and the protection device.

12. The light emitting device according to claim 11, further comprising
a convex guide part arranged around the first recessed part,
wherein the sealing layer covers an upper surface of the guide part.
